(19) United States
(12) Patent Application Publication
(10) Pub. No.: US 2010/0277450 A1
(43) Pub. Date: Nov. 4, 2010

(54) Display Device

(76) Inventors: Issei TAKEMOTO, Hiratsuka (JP); Eiji MATSUZAKI, Yokohama (JP); Yuji MORI, Urizura (JP); Nobuyuki USHIFUSA, Yokohama (JP); Hiroyasu MATSUURA, Yokohama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/836,167

(22) Filed: Jul. 14, 2010

Related U.S. Application Data
(62) Division of application No. 11/717,075, filed on Mar. 13, 2007.
Application No. 11/717,075 is a division of application No. 10/679,354, filed on Oct. 7, 2003, now abandoned.

(30) Foreign Application Priority Data
Oct. 16, 2002 (JP) 2002-301359

(51) Int. Cl. G09G 5/00

(52) U.S. Cl. 345/206

(57) ABSTRACT

A display device includes a first substrate having a display area with a plurality of pixels on a main surface and a first seal area formed at a periphery of the display area, and a second substrate disposed to cover the main surface of the first substrate, and having a second seal area at a part of the second substrate opposite to the first seal area. At least one driving circuit is arranged outside of the display area on the first substrate. The second substrate has a recessed portion formed at a part of the main surface of the second substrate within the second seal area, and a film coats the recessed portion and/or an outside of the second substrate. A moisture absorbent layer is arranged in the recessed portion so as to be adhered to the recessed portion or the film when the film coats the recessed portion.

### CROSS REFERENCE TO RELATED APPLICATION

This application is a divisional application of U.S. Ser. No. 11/717,075, filed Mar. 13, 2007 which is a divisional application of U.S. Ser. No. 10/679,354, filed Oct. 7, 2003, the contents of which are incorporated herein by reference.

### BACKGROUND OF THE INVENTION

The present invention relates to an active matrix type display device; and, more particularly, the invention relates to a display device which includes pixels constituted of light emitting elements, such as EL (electroluminescence) elements, which emit light by causing an electric current to flow to light emitting layers, such as organic semiconductor films, LED (light emitting diode) elements or the like, and pixel circuits which control the light emitting operation of these pixels.

Recently, along with the advent of a sophisticated information society, the demand for personal computers, a car navigation system, a PDA, information communication equipment and composite products thereof has been increasing. As display means for these products, a display device which is thin and light-weight and which exhibits a small power consumption is most suitable, and a liquid crystal display device or a self-luminous display device which uses electro-optical elements, such as EL elements or LEDs, has been used as such a display device. A display device which uses self-luminous electro-optical elements has favorable characteristics, such as a favorable visibility, a wide viewing angle characteristic and a rapid response suitable for display of moving images, whereby it is considered that such a display device is particularly suitable for image display.

Particularly, with respect to a display device which uses organic EL elements (also referred to as an organic LED element: hereinafter also abbreviated as OLED in some cases) which utilize an organic material, such as an organic semiconductor material, as light emitting layers, along with the rapid enhancement of the light emitting efficiency and the advancement of the network technology, which enables video communication, the expectation for a display device which uses OLED light emitting elements is high. An OLED light emitting element has a diode structure which sandwiches an organic light emitting layer between two sheets of electrodes.

To enhance the power efficiency of an OLED display device which is constituted of OLED light emitting elements, as will be explained later, active matrix driving, which uses thin film transistors (hereinafter also referred to as a TFT) as switching elements of the pixels, is effective. Techniques which drive the OLED display device using an active matrix structure are described in, for example, Japanese Unexamined Patent Publication 1992-328791, Japanese Unexamined Patent Publication 1996-241048, and US Patent Specification 5550066. Further, the drive voltages which are used to implement these techniques are referred to in International Patent Publication WO98/36407.

The display device which uses OLED light emitting elements consists of a first substrate on which there is formed a matrix of pixel circuits, each consisting of a switching element and an OLED light emitting element, on a main surface thereof, a second substrate laminated with the first substrate and which protects the OLED light emitting elements which are formed on the main surface of the first substrate, and a seal material, which is applied to the peripheries of both substrates and is cured so as to isolate and seal the inside of the laminated structure from the outside. Here, for mainly suppressing the deterioration of the OLED light emitting elements caused by moisture, a moisture absorbent member is usually mounted on an inner surface of the second substrate (surface which faces the main surface of the first substrate in an opposed manner). This moisture absorbent member is mounted in a recessed portion that is formed in the inner surface of the second substrate, and the moisture absorbent member is adhered to the recessed portion using an adhesive agent, or moisture absorbent material is applied to a bottom surface of the recessed portion by coating.

The aforementioned patent gazettes and the other documents relevant to the present patent application are listed as follows.

### Patent Document 1: Japanese Unexamined Patent Publication 1992-328791

### Patent Document 2: Japanese Unexamined Patent Publication 1996-241048

### Patent Document 3: US Patent Specification 5550066

### Patent Document 4: International Patent Publication WO98/36407

### Patent Document 5: Japanese Unexamined Patent Publication 2000-36381

### Patent Document 6: Japanese Unexamined Patent Publication 1997-148066

### SUMMARY OF THE INVENTION

The first substrate of a display device includes a display area formed of a pixel circuit in which a large number of pixels are arranged in a matrix array. The first substrate includes a first seal area at the periphery thereof outside the display area, and the second substrate includes a second seal area which covers the main surface constituting an inner surface of the first substrate at an area which faces the first seal area of the first substrate. Then, the first seal area and the second seal area are laminated to each other by way of a seal material, and ultraviolet rays are irradiated from the second substrate side to cure the seal material, thus completing sealing.

In the recent development of an OLED display device, a method has been proposed in which a drive circuit area, which constitutes drive circuits for driving the pixel circuits, is provided outside the display area, which is formed on the main surface of the first substrate, and inside the first seal area, and the drive circuits are arranged in the inside area sealed by the first substrate and the second substrate. In such a method, the drive circuits can be simultaneously formed with the pixel circuits and the drive circuits, and, hence, it is possible to obtain an advantage in that an operation to exteriorly mount the drive circuits can be omitted, and the constitution of the whole display device can be simplified.

However, in curing the seal material which laminates the first substrate and the second substrate together by irradiating ultraviolet rays to the seal material, there exists the possibility that the ultraviolet rays to be irradiated will wrap around the drive circuit area and the display area and deteriorate the characteristics of the drive circuits and the semiconductor films which constitute the pixel circuits in the display area. Accordingly, in performing curing of the seal material by the irradiation of ultraviolet rays, it is necessary to prevent wrapping-around of the ultraviolet rays around the drive circuit area and the display area.

As a countermeasure to cope with this problem, the use of a light shielding mask, which is used in the manufacture of semiconductor elements, has been considered conventionally. As will be explained later as a comparison with an exemplary embodiment, such curing treatment of the seal material is performed by using a quartz mask which constitutes a light shielding film on portions which are to be blocked from the irradiation of ultraviolet rays, and the quartz mask is tightly adhered to the second substrate. However, in using such a method, since there is a distance between the drive circuits, the pixel circuits and the quartz mask, the wrapping-around of the ultraviolet rays into the inside of the light shielding film formed on the quartz mask is increased. Accordingly, it is necessary to form the drive circuits such that the drive circuits are arranged close to the display area side. However, this brings about a narrowing of the display area.

As another examples, Japanese Unexamined Patent Publication 2000-36381 and Japanese Unexamined Patent Publication 1997-148066 propose a technique in which cathode films which constitute OLED elements in a display area are formed of a light shielding metal. This structure, however, is not intended to perform light shielding of drive circuits in a display device which includes a structure in which the drive circuits are provided inside a sealed area.

It is an object of the present invention to provide a display device which has a structure in which a drive circuit area is provided inside a sealed area between a first substrate and a second substrate that are laminated together and which can obviate in a simple structure deterioration of the characteristics of a display area (a plurality of pixels each having an active element being arranged) and the drive circuit area, which may be caused by the irradiation of ultraviolet rays, without using a special device for light shielding.

To achieve the above-mentioned object, the present invention is characterized in that light shielding means is arranged close to the display area where pixel circuits to be blocked from light are formed and the drive circuit area where the drive circuit is formed, and respective types of constitutional layers provided to the display device also function as the light shielding means. The present invention particularly adopts a structure in which cathode films which constitute OLED elements of the display area on the first substrate also shield the drive circuit area. Further, layers or films made of a moisture absorbent material which are provided to the second substrate are used as light shielding means, or a light shielding film which covers the display area or the drive circuit area is formed over an inner surface or an outer surface of the second substrate.

Due to such structures, a projected image of the light shielding film or the light shielding layer, as viewed from the ultraviolet ray irradiation side, covers the drive circuit area beyond the display area, and, hence, the ultraviolet rays are irradiated only to a seal material in the seal area, without using a special light shielding device in the manufacturing steps, whereby it is possible to prevent deterioration of the characteristics of the organic light emitting layers and semiconductor films which constitute the pixel circuits and the semiconductor films which constitute the drive circuit, thus providing a display device of high quality.

A display device according to a first example of the present invention comprises:

(a) a first substrate having a display area in which a plurality of pixels are arranged in a matrix array on a main surface of the first substrate, and a first seal area formed at a periphery of the display area on the main surface of the first substrate, each of the plurality of pixels has a light emitting element and a pixel circuit including an active element; and
(b) a second substrate disposed to cover the main surface of the first substrate with a main surface of the second substrate, and having a second seal area at a part of the main surface of the second substrate opposite to the first seal area of the first substrate, the first substrate and the second substrate being stuck to each other by a seal material interposed between the first seal area and the second seal area, wherein
(1) the first substrate has a cathode film which is commonly utilized for the respective light emitting elements of the plurality of pixels and covers the second substrate side of the display area,
(2) at least one driving circuit for driving the plurality of pixels is arranged outside of the display area on the main surface of the first substrate,
(3) the second substrate has a recessed portion formed at a part of the main surface of the second substrate within the second seal area and a moisture absorbent layer adhering to the recessed portion, and
(4) the cathode film has a light shielding property and is formed beyond the display area to cover said at least one driving circuit also.

In the display device according to the first example, the cathode film may be formed as a single layer of a conductive film, or it may have a laminated structure formed by stacking a plurality of conductive films. The conductive film is formed of e.g. a material selected from a group consisting of aluminum, chromium, titanium, molybdenum, tungsten, hafnium, yttrium, copper, silver, and an alloy which contains at least two elements selected from a group consisting of aluminum, chromium, titanium, molybdenum, tungsten, hafnium, yttrium, copper, and silver. Moreover, the cathode film should be thick enough to cut off ultraviolet rays with which the seal material is irradiated so as to be cured.

On the other hand, the light emitting element may be formed of an organic semiconductor material, or it may have a light emitting layer formed of an organic electroluminescent material.

Furthermore, in the aforementioned display device according to the first example, an area where the at least one driving circuit is provided does not extend outside of the first seal area on the main surface of the first substrate. The first seal area may be formed to surround the display region disposed in the main surface of the first substrate. The second seal area may be formed to surround the recessed portion formed at the main surface of the second substrate in the main surface thereof.

A display device according to a second example of the present invention comprises:

(a′) a first substrate having a display area in which a plurality of pixels are arranged in a matrix array on a main surface of the first substrate, and a first seal area formed at a periphery of the display area on the main surface of the first substrate, each of the plurality of pixels includes a light emitting element and an active element; and
(b) a second substrate disposed to cover the main surface of the first substrate with a main surface of the second substrate, and having a second seal area at a part of the main surface of the second substrate opposite to the first seal area of the first substrate, the first substrate and the second substrate being stuck to each other by a seal material interposed between the first seal area and the second seal area, wherein
(2) at least one driving circuit for driving the plurality of pixels is arranged outside of the display area on the main surface of the first substrate,
(3′) the second substrate has a recessed portion formed at a part of the main surface of the second substrate within the second seal area and a moisture absorbent layer having a light shielding property adheres to the recessed portion, and
(5′) the moisture absorbent layer is arranged to cover the display area and the at least one driving circuit.

In the display device according to the second example, the moisture absorbent layer may be formed of a moisture absorbent material containing pigments dispersed therein. The pigments cut off ultraviolet with which the seal material is irradiated so as to be cured, and they are formed e.g. of a material selected from a group consisting of carbon black and titanium black.

On the other hand, the moisture absorbent layer may be formed of a moisture absorbent containing dye mixed therein, also. The dye cuts off ultraviolet rays with which the seal material is irradiated so as to be cured.

In the display device according to the second example, the moisture absorbent layer may be adhered to the recessed portion of the main surface of the second substrate with an adhesive. The adhesive may contain pigments blocking ultraviolet rays with which the seal material is irradiated so as to be cured. The pigments are formed of a material selected from a group consisting of carbon black and titanium black, for instance. The adhesive may also contain a dye mixed therein. The dye blocks ultraviolet rays with which the seal material is irradiated so as to be cured.

A display device according to a third example of the present invention comprises:

(a′) a first substrate having a display area in which a plurality of pixels are arranged in a matrix array on a main surface of the first substrate and a first seal area formed at a periphery of the display area on the main surface of the first substrate, each of the plurality of pixels includes a light emitting element and an active element; and
(b) a second substrate disposed to cover the main surface of the first substrate with a main surface of the second substrate, and having a second seal area at a part of the main surface of the second substrate opposite to the first seal area of the first substrate, the first substrate and the second substrate being stuck to each other by a seal material interposed between the first seal area and the second seal area, wherein
(2) at least one driving circuit for driving the plurality of pixels is arranged outside of the display area on the main surface of the first substrate,
(3″) the second substrate has a recessed portion formed at a part of the main surface of the second substrate within the second seal area and a coating film of a moisture absorbent layer having a light shielding property is put in the recessed portion, and
(5) the moisture absorbent layer is arranged to cover the display area and the at least one driving circuit.

A display device according to a fourth example of the present invention comprises:

(a′) a first substrate having a display area in which a plurality of pixels are arranged in a matrix array on a main surface of the first substrate, and a first seal area formed at a periphery of the display area on the main surface of the first substrate, each of the plurality of pixels includes a light emitting element and an active element; and
(b) a second substrate disposed to cover the main surface of the first substrate with a main surface of the second substrate, and having a second seal area at a part of the main surface of the second substrate opposite to the first seal area of the first substrate, the first substrate and the second substrate being stuck to each other by a seal material interposed between the first seal area and the second seal area, wherein
(2) at least one driving circuit for driving the plurality of pixels is arranged outside of the display area on the main surface of the first substrate,
(6) the second substrate has a recessed portion formed at a part of the main surface of the second substrate within the second seal area and a light shielding film covering the display area and the at least one driving circuit is put in the recessed portion, and
(7) a moisture absorbent layer adheres on the light shielding film.

A display device according to a fifth example of the present invention comprises:

(a′) a first substrate having a display area in which a plurality of pixels are arranged in a matrix array on a main surface of the first substrate, and a first seal area formed at a periphery of the display area on the main surface of the first substrate, each of the plurality of pixels includes a light emitting element and an active element; and
(b) a second substrate disposed to cover the main surface of the first substrate with a main surface of the second substrate, and having a second seal area at a part of the main surface of the second substrate opposite to the first seal area of the first substrate, the first substrate and the second substrate being stuck to each other by a seal material interposed between the first seal area and the second area, wherein
(2) at least one driving circuit for driving the plurality of pixels is arranged outside of the display area on the main surface of the first substrate,
(8) the second substrate has a recessed portion formed at a part of the main surface of the second substrate which is opposite to the main surface of the first substrate and located within the second seal area, a moisture absorbent layer adhering to the recessed portion, and a light shielding film being arranged on another main surface thereof at an opposite side thereof to the main surface of the first substrate and covering the display area and the at least one driving circuit.

A display device according to a sixth example of the present invention comprises:

(a′) a first substrate having a display area in which a plurality of pixels are arranged in a matrix array on a main surface of the first substrate and a first seal area formed at a periphery of the display area on the main surface of the first substrate, each of the plurality of pixels includes a light emitting element and an active element; and
(b) a second substrate disposed to cover the main surface of the first substrate with a main surface of the second substrate, and having a second seal area at a part of the main surface of the second substrate opposite to the first seal area of the first substrate, the first substrate and the second substrate being stuck to each other by a seal material interposed between the first seal area and the second seal area, wherein
(1) the first substrate has a cathode film which is commonly utilized for the respective light emitting elements of the plurality of pixels and covers the second substrate side of the display area,
(2′) at least one driving circuit for driving the plurality of pixels is arranged in a portion of the main surface of the first substrate being outside of the display area and extending from a part of the first seal area to an inside of the first seal area,
(3) the second substrate has a recessed portion formed at a part of the main surface of the second substrate within the second seal area and a moisture absorbent layer adhering to the recessed portion, and
(4) the cathode film has a light shielding property and is formed beyond the display area to cover the at least one driving circuit also.

In each of the aforementioned display devices according to the second through sixth examples, the light emitting element may be formed of an organic semiconductor material, or it may have a light emitting layer formed of an organic electroluminescent material.

Here, it is needless to say that the present invention is not limited to the above-mentioned constitutions and the constitutions of embodiments to be described later, and various modifications are conceivable without departing from the technical concept of the present invention. Other objects and features of the present invention will become apparent from the description of the embodiments described hereinafter.

### BRIEF DESCRIPTION OF THE DRAWINGS

FIG. 1 is a cross-sectional view schematically showing the constitution of a first embodiment of a display device according to the present invention;

FIG. 2 is a cross-sectional view schematically showing the constitution of a second embodiment of a display device according to the present invention;

FIG. 3 is a cross-sectional view schematically showing the constitution of a third embodiment of a display device according to the present invention;

FIG. 4 is a cross-sectional view schematically showing the constitution of a fourth embodiment of a display device according to the present invention;

FIG. 5 is a cross-sectional view schematically showing the constitution of a fifth embodiment of a display device according to the present invention;

FIG. 6 is a cross-sectional view schematically showing the constitution of a sixth embodiment of a display device according to the present invention;

FIG. 7 is a schematic cross-sectional view of a conventional ultraviolet-ray exposure device;

FIG. 8 is a diagram showing an example of a manufacturing process used in the production of a display device according to the present invention;

FIG. 9 is a process flow chart representing one example of the manufacturing process shown in FIG. 8;

FIG. 10 is a plan view schematically showing an example of the arrangement of respective functional parts on a first substrate of a display device according to the present invention;

FIG. 11 is a schematic circuit diagram of one pixel of the display device shown in FIG. 10; and

FIG. 12 is a cross-sectional view schematically showing an example of the layer structure in the vicinity of one pixel of a display device using organic light emitting elements to which the present invention is applied.

### DETAILED DESCRIPTION

Preferred embodiments of the present invention will be explained in detail in conjunction with drawings. In the explanation provided hereinafter, the organic light emitting layers of light emitting elements which constitute respective pixel circuits are classified into organic light emitting layers which perform a monochromic or color display by emitting light with a luminance which is substantially proportional to a current value and with a color (including white) depending on the organic material thereof, organic light emitting layers which perform a color display by combining color filters of red, green, blue and the like to organic layers which emit white light, and the like. Here, since the details of the mechanism of light emission, coloration and the like are not directly relevant an understanding of the present invention, an explanation thereof will be omitted.

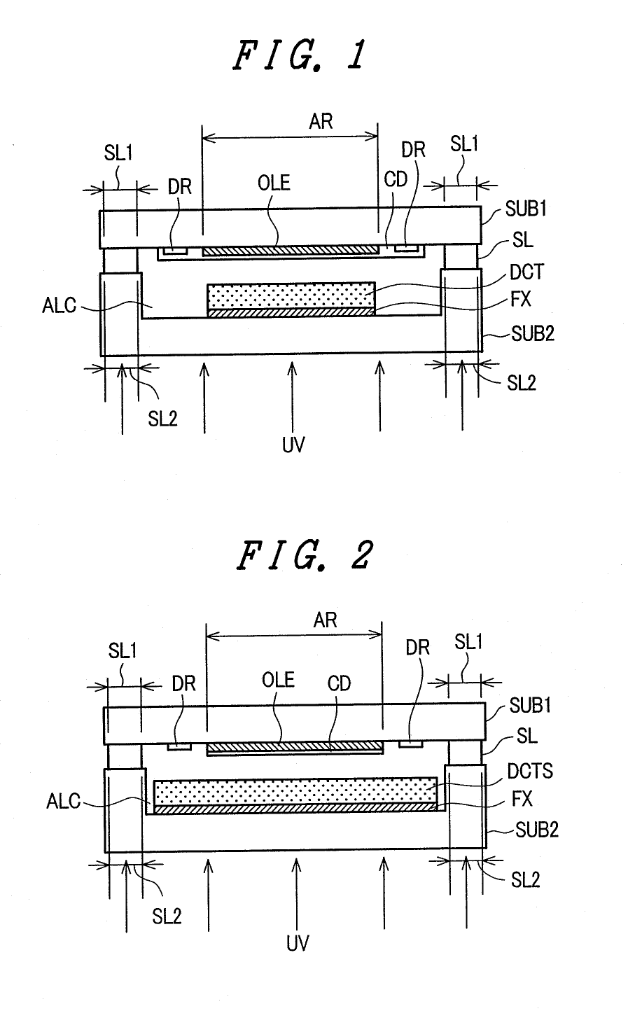

FIG. 1 is a cross-sectional view schematically showing the constitution of a first embodiment of a display device according to the present invention. In the drawing, reference symbol SUB1 indicates a first substrate, reference symbol SUB2 indicates a second substrate, and reference symbol SL indicates a seal material. On an inner surface, which constitutes a main surface, of the first substrate SUB1, organic light emitting elements formed of organic light emitting layers OLE are formed. In FIG. 1, only the organic light emitting layer OLE and a cathode film CD, which is formed as a layer above the organic light emitting layer OLE, are shown. The organic light emitting element includes pixel circuits constituted of a plurality of thin film transistors and holding capacitances as active elements for selecting and driving the pixel on the organic light emitting layer OLE for each pixel. A display area AR is formed of a large number of these pixels. Outside the display area AR and inside the seal SL (an area inside of where a seal area SL1 at the first substrate SUB1 side and a seal area SL2 at the second substrate SUB2 side face each other in an opposed manner), a drive circuit area DR, where drive circuits are formed, is positioned. Here, the active elements are not limited to thin film transistors.

The display device includes the display area AR, in which the pixel circuits are arranged in a matrix array on the main surface of the first substrate SUB1 and the drive circuit area DR, where the drive circuits are formed. The cathode films CD, which constitute the pixel circuits, are provided in the display area AR, and these cathode films CD are formed, so as to also cover the drive circuit area DR beyond the display area AR. The second substrate SUB2 is a so-called seal can, wherein a recessed portion ALC is formed in the second substrate SUB2, that is, in a surface of the second substrate SUB2 which faces the main surface of the first substrate SUB1. A moisture absorbent member (desiccant agent) DCT is mounted in the recessed portion by way of an adhesive layer FX.

The seal areas SL1, SL2 are formed on respective peripheries of the first substrate SUB1 and the second substrate SUB2, and the seal material (adhesive agent made of ultraviolet ray cuing resin) SL is applied between these seal areas SL1, SL2. The first substrate SUB1 and the second substrate SUB2 are laminated to each other such that the respective main surfaces thereof face each other in an opposed manner, and the distance between both substrates is adjusted to a given value (so-called gap forming step). At this point of time, the seal material SL is sandwiched between the seal area SL1 of the first substrate SUB1 and the seal area SL2 of the second substrate SUB2 in a state such that the seal material SL is not cured. Subsequently, ultraviolet rays UV are directed to be incident on the second substrate SUB2 (main surface of the second substrate SUB2 opposite to the first substrate SUB1). The seal material SL is cured upon receiving the irradiation of ultraviolet rays UV which pass through the second substrate SUB2 (peripheral portion which surrounds the recessed portion ALC). Accordingly, the first substrate SUB1 and the second substrate SUB2 are integrally fixed to each other by the cured seal material SL. In the display device (display panel) assembled in this manner, the main surfaces (main surfaces having the seal areas SL1, SL2) of the first substrate SUB1 and the second substrate SUB2 which face each other in an opposed manner are referred to as inner surfaces, while the main surface of the first substrate SUB1 opposite to the second substrate SUB2 and the main surface of the second substrate SUB2 opposite to the first substrate SUB1 are referred to as outer surfaces.

Here, the irradiated ultraviolet rays UV are blocked by the cathode films CD which are formed on the inner surface of the first substrate SUB1 and do not reach the display area AR and the drive circuit area DR. The wavelength of the ultraviolet rays UV is usually 300 nm to 450 nm and the intensity of light is 10 to 200 mW/cm². Further, to ensure the light shielding effect of the cathode films CD, it is preferable to set the thickness of the cathode films CD such that the cathode films CD can sufficiently block light in the above-mentioned wavelength band. For example, when the cathode films CD are formed of aluminum, it is preferable to set the thickness of the cathode film CD to a value equal to or more than 50 nm, and it is more preferable to set the thickness of the cathode films CD to a value equal to or more than 200 nm. With respect to an aluminum film, the light shielding effect is almost saturated when the film thickness of the cathode film CD is equal to or more than 200 nm.

When the cathode films are made of aluminum, by setting the film thickness to a value equal to or more than 200 nm, no damage is imparted to the semiconductor films of the organic light emitting layers OLE which constitute the display area AR or to the thin film transistors and the semiconductor films of the thin film transistors which constitute the drive circuit area DR. According to this embodiment, without adding a particular light shielding means, it is possible to shield the display area AR and the drive circuit area DR of the display device from ultraviolet rays, and, hence, it is possible to maintain a given performance (voltage/current characteristics) for a long period, and, at the same time, it is possible to obtain a display device of high quality at a low cost. That is, without adding any new functions to the existing manufacturing facility and, at the same time, without adding a new forming process, it is possible to manufacture the display device of the present invention. The cathode films CD may be formed of a metal film made of a material selected from a group consisting of aluminum, chromium, titanium, molybdenum, tungsten, hafnium, yttrium, copper and silver or an alloy film made of a material containing the above-mentioned two or more materials.

FIG. 2 is a cross-sectional view schematically showing the constitution of a second embodiment of the display device according to the present invention.

In the drawing, the same reference symbols as those in FIG. 1 indicate identical functional parts. While the embodiment described in conjunction with FIG. 1 performs light shielding at the first substrate SUB1 side, in this embodiment, the display area AR and the drive circuit area DR provided on the first substrate SUB1 are shielded from light by a moisture absorbent layer DCTS provided on the second substrate SUB2. To obviate any contact between the display area AR and the drive circuit area DR provided at the inner surface of the first substrate SUB1, the thickness of the moisture absorbent layer DCTS is usually set to 0.1 to 1.0 mm. The moisture absorbent layer DCTS is a sheet-like molded product and is fixed to a bottom portion of the recessed portion ALC of the second substrate SUB2 by means of an adhesive agent FX.

Provided that the moisture absorbent layer DCTS is a material which can block ultraviolet rays having a wavelength of 300 nm to 450 nm, known materials can be used. A material which is produced by blending 1% to 30% by weight of black powder, such as carbon black or titanium black to a material known as a desiccant (for example, a composition which contains barium oxide, calcium oxide, zeolite and the like as main components) can be used. Here, in this embodiment, although the cathode films CD provided on the first substrate SUB1 side are formed such that the cathode films CD cover only the display area AR, it is possible to enhance the light shielding effect by forming the cathode films CD so as to also cover the drive circuit area DR in the same manner as the above-mentioned first embodiment. For example, it is possible to prevent UV rays from leaking through the shielding attributed to pin hole defects when the cathode films CD are made of aluminum, and, at the same time, it is possible to set the thickness of the aluminum cathode films CD to equal to or less than 200 nm. According to this embodiment, without adding a particular light shielding means, it is possible to shield the display area AR and the drive circuit area DR of the display device from the ultraviolet rays, and, hence, it is possible to maintain a given performance (voltage/current characteristics), and, at the same time, it is possible to obtain a display device of high quality at a low cost.

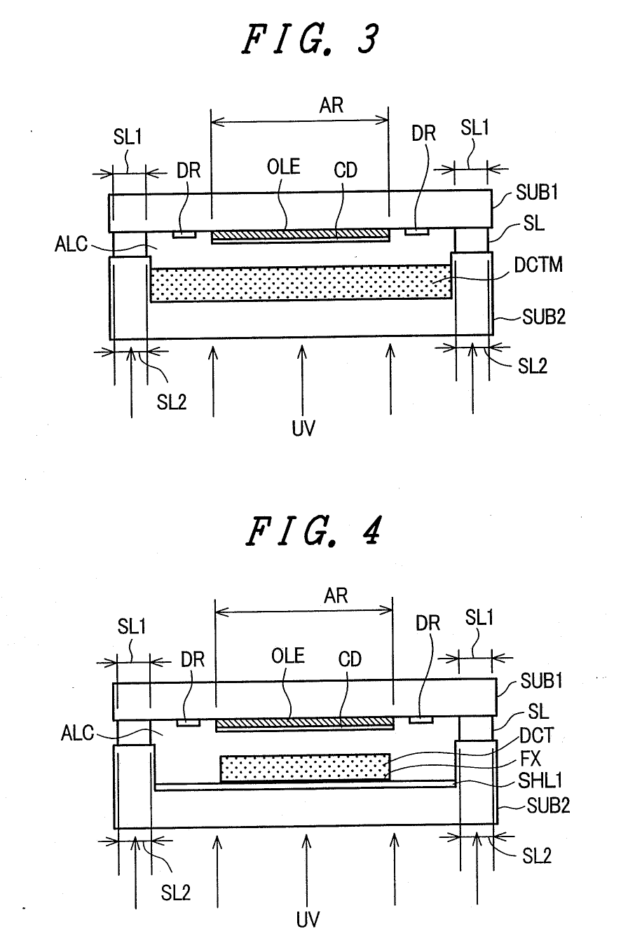

FIG. 3 is a cross-sectional view schematically showing the constitution of a third embodiment of the display device according to the present invention. A repeated explanation of structural features similar to those shown in FIG. 1 and FIG. 2 will be omitted. In this embodiment, as a moisture absorbent member which is mounted in the recessed portion ALC formed in the inner surface of the second substrate SUB2, a moisture absorbent material in a liquid form is applied to the whole surface of the bottom portion of the recessed portion ALC of the second substrate SUB2 and is fixed to the bottom portion by heat treatment, thus forming a moisture absorbent film DCTM. Accordingly, in this embodiment, an adhesive agent for fixing the moisture absorbent film DCTM is unnecessary. As the material of the moisture absorbent film DCTM, it is possible to use a material similar to the material used in the second embodiment, which was described in conjunction with FIG. 2. Further, by forming the cathode film CD so that it also covers the drive circuit area DR in the same manner as the first embodiment, it is possible to further enhance the light shielding effect. According to this embodiment, without adding a particular light shielding means, it is possible to shield the display area AR and the drive circuit area DR of the display device from ultraviolet rays, and, hence, it is possible to maintain a given performance (voltage/current characteristics), and, at the same time, it is possible to obtain a display device of high quality at a low cost.

FIG. 4 is a cross-sectional view schematically showing the constitution of a fourth embodiment of the display device according to the present invention. A repeated explanation of structural features similar to those shown in FIG. 1 to FIG. 3 will be omitted. In this embodiment, a light shielding film SHL1 is formed in the recessed portion ALC formed in the inner surface of the second substrate SUB2, and a moisture absorbent layer DCT is fixed to the light shielding film SHL1 as an upper layer using the adhesive agent FX. The light shielding film SHL1 may be obtained by applying or printing a light-shielding composition in a liquid form (resin which is produced by dispersing black powder made of carbon black or titanium black or the like into a solvent) to the recessed portion ALC and drying the composition, or it may be obtained by forming a film having a given thickness by vacuum evaporating or sputtering a metal material. Further, an inorganic or organic light shielding composition in a film form may be laminated to the recessed portion ALC. Further, by forming the cathode film CD, so that it also covers the drive circuit area DR in the same manner as the first embodiment, it is possible to further enhance the light shielding effect. According to this embodiment, without adding a particular light shielding means, it is possible to shield the display area AR and the drive circuit area DR of the display device from ultraviolet rays, and, hence, it is possible to maintain a given performance (voltage/current characteristics), and, at the same time, it is possible to obtain a display device of high quality at a low cost.

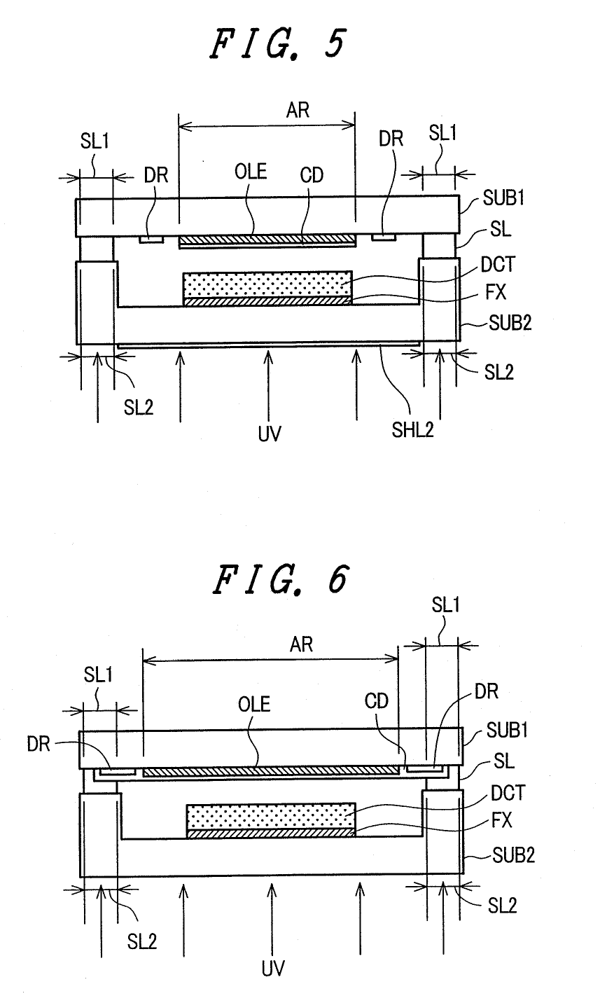

FIG. 5 is a cross-sectional view schematically showing the constitution of a fifth embodiment of the display device according to the present invention. A repeated explanation of structural features similar to those shown in FIG. 1 to FIG. 4 will be omitted. In this embodiment, a light shielding film SL2, similar to the light shielding film SL1 described in conjunction with FIG. 4, is formed on the outer surface of the second substrate SUB2. The light shielding film SL2 may be obtained by applying or printing a light-shielding composition in a liquid form (resin which is produced by dispersing black powder made of carbon black or titanium black or the like into a solvent) to the outer surface of the second substrate SUB2 and drying the composition, or it may be obtained by forming a film having a given thickness by vacuum evaporating or sputtering a metal material. Further, an inorganic or organic light shielding composition in a film form may be laminated to the outer surface of the second substrate SUB2. Further, by forming the cathode films CD so that it also covers the drive circuit area DR in the same manner as the first embodiment, it is possible to further enhance the light shielding effect. According to this embodiment, without adding a particular light shielding means, it is possible to shield the display area AR and the drive circuit area DR of the display device from ultraviolet rays, and, hence, it is possible to maintain a given performance (voltage/current characteristics), and, at the same time, it is possible to obtain a display device of high quality at a low cost.

FIG. 6 is a cross-sectional view schematically showing the constitution of a sixth embodiment of the display device according to the present invention. A repeated explanation of structural features similar to those shown in FIG. 1 to FIG. 4 will be omitted. In this embodiment, the drive circuit area DR, which is provided on the main surface of the first substrate SUB1, is formed so that it is overlapped on portions of the seal area (where the seal area SL1 of the first substrate SUB1 side and the seal area SL2 of the second substrate SUB2 side face each other). Although the overall constitution of this embodiment is substantially the same as the overall constitution of the first embodiment of the present invention, as described in conjunction with FIG. 1, this embodiment differs from the first embodiment in that the drive circuit area DR is formed at a position where the drive circuit extends into the seal area. Since the other structural features are the same as shown in FIG. 1, a repeated explanation thereof will be omitted.

According to this embodiment, by forming the drive circuit area DR at the position where the drive circuit extends into the seal area, it is also possible to increase the display area AR, and, hence, a display device having a large screen can be realized without increasing the size of the substrate. Here, although the constitution of the first substrate SUB1 side is formed in the same manner as the constitution shown in FIG. 1, it also may be formed in the same manner as the constitutions described in conjunction with FIG. 2 to FIG. 5. Further, the constitution of the second substrate SUB2 side may be formed in the same manner as the constitutions described in conjunction with FIG. 2 to FIG. 5. According to this embodiment, without adding a particular light shielding means, it is possible to shield the display area AR and the drive circuit area DR of the display device from ultraviolet rays, and, hence, it is possible to maintain a given performance (voltage/current characteristics), and, at the same time, it is possible to obtain a display device of high quality at a low cost.

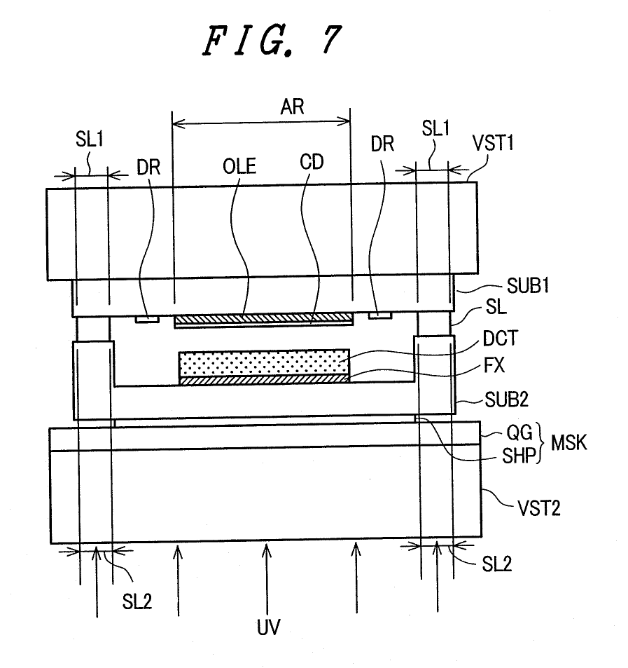

Now, a comparison example will be described to highlight the features of the present invention. FIG. 7 is a schematic cross-sectional view of a conventional ultraviolet-ray exposure device for explaining the advantageous effects of the present invention. Conventionally, a light shielding mask MSK, which includes a light shielding film SHP formed on a quartz glass QG, is tightly adhered to an outer surface of the second substrate SUB2, and ultraviolet rays UV are irradiated to a seal material SL from the second substrate SUB2 side. To prevent leaking of the ultraviolet rays UV incident on one of the main surfaces (lower surface shown in FIG. 7) of the second substrate SUB2 to the display area AR (active elements of respective pixels arranged inside thereof) and the drive circuit area DR (drive circuits including active elements) of the first substrate SUB1, the light shielding mask MSK is tightly adhered to one of main surfaces (lower surface shown in FIG. 7 on which the ultraviolet rays UV are incident) of the second substrate SUB2 in accordance with steps to be described hereinafter.

First of all, the light shielding mask MSK is placed on a transparent lower suction stage VST2, and the second substrate SUB2 is placed on the light shielding mask MSK. A seal material SL, for example, from a dispenser is applied to the periphery (seal area SL2) of the main surface of the second substrate SUB2. Then, the first substrate SUB1 is conveyed by an upper suction stage VST1, provided with a vacuum chuck, to a position above the second substrate SUB2 in a state in which the main surface of the first substrate SUB1, on which the display area AR and the drive circuit area DR are formed, faces downwardly. Subsequently, the positions of the upper suction stage VST1 and a lower suction stage VST2 are adjusted horizontally. Next, the periphery (seal area SL1) of the main surface of the first substrate SUB1 is brought into contact with the seal material SL that has been applied to the periphery of the main surface of the second substrate SUB2. Thus, the main surface of the first substrate SUB1 and the main surface of the second substrate SUB2 are laminated to each other with a given distance therebetween. In this state, ultraviolet rays UV, incident on the periphery of the second substrate SUB2 from the lower suction stage VST2 side, are irradiated to the seal material SL so as to cure the seal material SL.

However, as described previously, since a large distance exists between the area to be blocked from the light and the light shielding mask, it is difficult to prevent the irradiation of ultraviolet rays to the area to be blocked from the light, so that unwanted irradiation is caused by wrapping-around of the ultraviolet rays. Particularly, it is difficult to obviate the damage which may be caused by the wrapping-around of the ultraviolet rays to the drive circuit area adjacent to the seal material SL.

Further, such a ultraviolet-ray exposure device uses an expensive quartz mask, and, hence, the device is not suitable for the manufacture of a display device having a large screen size. Further, since the light shielding mask MSK and the second substrate SUB2 must be held using the same lower suction stage VST2, the holding mechanism becomes complicated. Further, an alignment of three components, consisting of the first substrate SUB1, the second substrate SUB2 and the light shielding mask MSK, becomes necessary, and, hence, it is inevitable that the mechanism for alignment becomes complicated. Further, the light shielding film SHP, which is usually formed of a chromium film, is brought into contact with the second substrate SUB2, and, hence, flaws or the like occur on the light shielding film SHP, so that there is a limit to the repeated use of the light shielding film SHP. In view of the above, when the ultraviolet-ray exposure device shown in FIG. 7 is used, this increases the cost of the display device. Accordingly, by adopting the above-mentioned respective embodiments of the present invention, it is possible to shield the display area AR and the drive circuit area DR from ultraviolet rays without adding any special light shielding means.

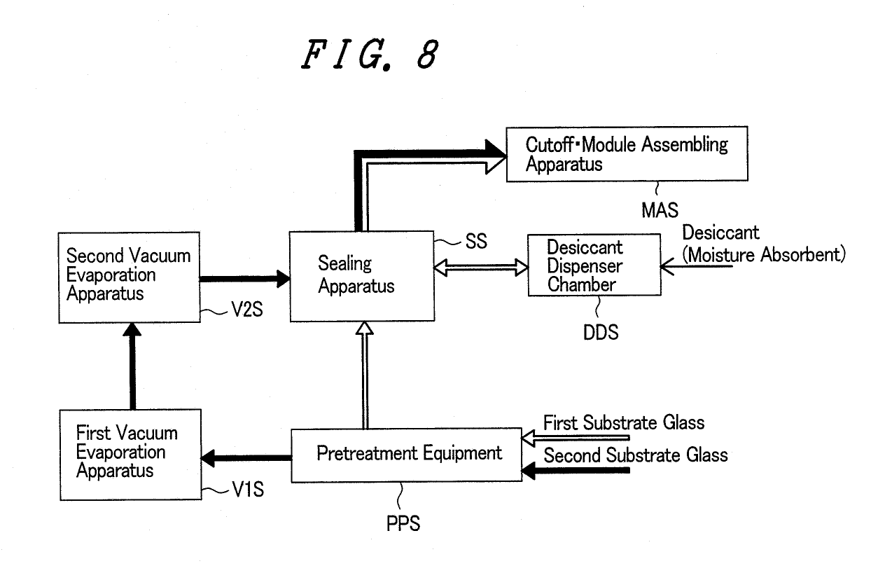

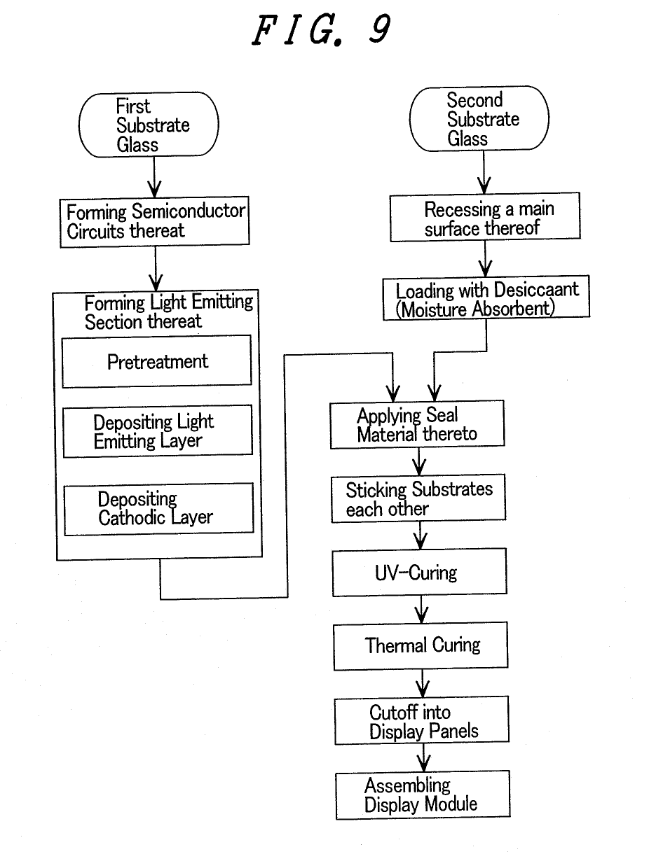

FIG. 8 is a block diagram showing an example of a manufacturing process used in the fabrication of the display device according to the present invention. FIG. 9 is a process flow chart for explaining an example of the manufacturing process shown in FIG. 8. In FIG. 8, glass (first substrate glass) which constitutes a base material of the first substrate and glass (second substrate glass) which constitutes a base material of the second substrate are subjected to cleaning, degassing, cooling and the like, respectively, by a pretreatment facility PPS. Here, a recessed portion in which a moisture absorbent (desiccant) material is mounted is formed in the second substrate glass. Then, the first substrate glass is conveyed to a first vacuum evaporation apparatus V1S and hole injection layers and organic light emitting layers are formed on output electrodes (or anodes connected to the output electrodes) of the thin film transistors. When the color display is performed with light emitting colors of the organic light emitting layers per se, the formation of organic light emitting layers of three colors consisting of red (R), green (G) and blue (B) is performed sequentially.

The first substrate glass to which the treatment in the first vacuum evaporation apparatus V1S has been applied is conveyed to a second vacuum evaporation apparatus V2S where the vacuum evaporation or the like of the cathodes is applied. The first substrate glass on which the cathodes have been deposited is conveyed to a sealing apparatus SS. On the other hand, the pretreated second substrate glass is conveyed to the sealing apparatus SS and, thereafter, they are transferred to a desiccant dispenser chamber (moisture absorbent loading chamber) DDS, where a moisture absorbent is loaded in the recessed portion. The second substrate glass on which the moisture absorbent is loaded is again returned to the sealing apparatus SS and is laminated to the first substrate glass. This lamination is performed such that a seal material made of an ultraviolet ray curing resin is applied between respective seal areas of the first substrate glass and the second substrate glass and the substrate glasses are laminated to each other. Ultraviolet rays are radiated to the seal material from the second substrate glass side to cure the seal material. Here, it may be possible to perform the heat treatment after irradiation of the ultraviolet rays so as to completely cure the seal material.

The laminated product, which was formed by integrally laminating the first and the second substrate glasses using the seal material and by curing the seal material, is taken out from the sealing apparatus SS and is cut into individual display devices. A flexible printed circuit board for signal connection is mounted on the display device, aging treatment is applied to the display device, and, thereafter, the display device is incorporated into a housing, thus completing the fabrication of the display device.

The above-mentioned manufacturing process will be further explained in conjunction with FIG. 9. First of all, on the base-material glass substrate which constitutes the first substrate glass (first substrate glass), the thin film transistor and the semiconductor circuit, which functions as the driver circuit for the thin film transistor, which constitute the pixel circuit for the organic light emitting element, are formed for every display device. The light emitting layer of the organic light emitting element OLE is formed on the first substrate glass. In forming the OLE light emitting layer, the pretreatments, such as cleaning, degassing, cooling and the like, are applied to the substrate, which includes the thin film transistor circuit formed in the preceding step, and, thereafter, the hole injection layer and the organic light emitting layer are applied to each pixel portion of the display area. Finally, the cathode film is formed to obtain the first substrate.

On the other hand, the recessed portion, which houses the moisture absorbent material therein, is formed in the second substrate glass which constitutes the sealing substrate. The moisture absorbent material is loaded on the second substrate glass after forming the recessed portion, and, thereafter, the second substrate glass is laminated to the first substrate glass by applying the seal material. After curing the seal material by the irradiation of ultraviolet rays, heat treatment is applied as a post-curing treatment. Thereafter, the laminated product is cut into individual-sized display devices. The flexible printed circuit board for connection with the external circuit is connected to the display device, and, thereafter, the display device is incorporated into the housing, whereby the display device is completed as a module.

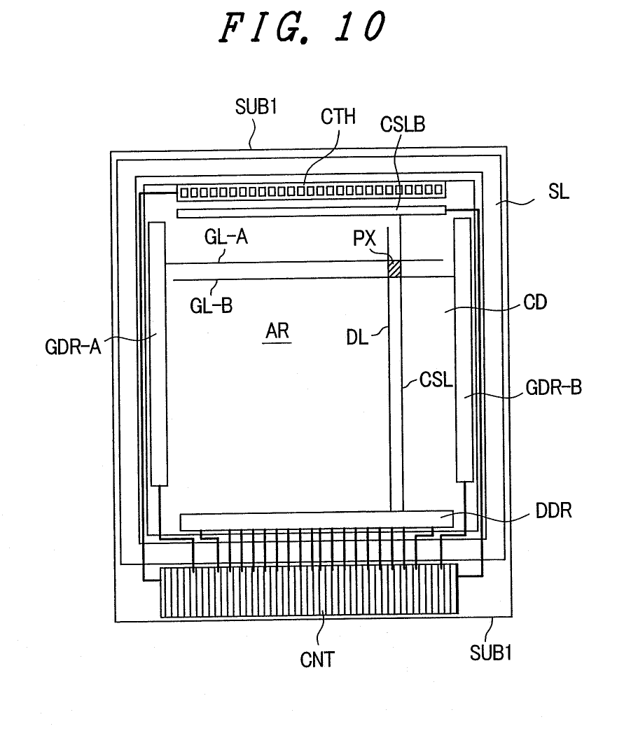

FIG. 10 is a plan view schematically showing an example of the arrangement of respective functional portions on the first substrate of the display device according to the present invention. The display device shown in FIG. 10 corresponds to the above-mentioned first embodiment of the present invention. On the largest portion at the center of the first substrate SUB1, the display area AR is formed. In this drawing, at both sides, that is, at the left and the right sides of the display area AR, drive circuits (scanning drive circuit) GDR-A and GDR-B are arranged. Gate lines GL-A, GL-B which extend from the respective scanning drive circuits GDR-A and GDR-B are alternately formed. Further, another drive circuit (data drive circuit) DDR is arranged at the lower side of the display area AR, and drain lines DL which constitute data lines are formed such that the drain lines DL intersect the gate lines GL-A, GL-B.

Further, a current supply base line CSLB is arranged at the upper side of the display area AR, and current supply lines CSL extending from the current supply base line CSLB are formed. In this constitution, one pixel PX is formed in the area defined by the gate lines GL-A, GL-B, the drain line DL and the current supply line CSL. Then, inside the seal material SL, the cathode films CD are formed so as to cover the display area AR, the respective scanning drive circuits GDR-A, GDR-B and the data drive circuit DDR. Here, reference symbol CTH indicates a contact area which is used for connecting the cathode films to cathode film lines which are formed as a layer below the first substrate.

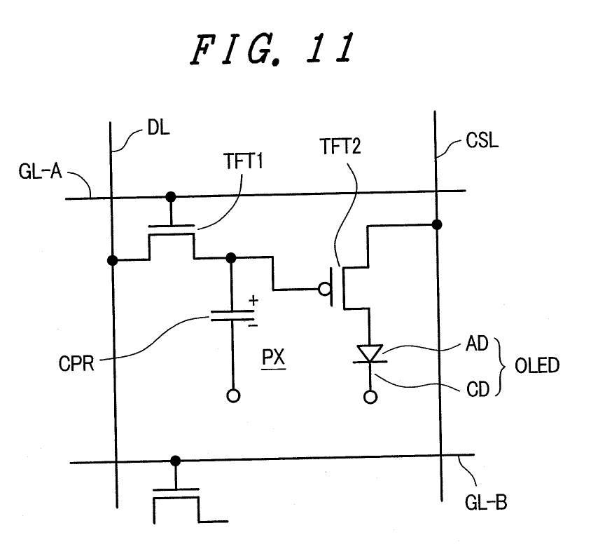

FIG. 11 is a schematic circuit diagram showing an example of the circuit constitution of one pixel shown in FIG. 10. The pixel is constituted of a thin film transistor TFT1 for switching, a thin film transistor TFT2 for driving organic light emitting element OLED and a capacitance CPR for holding data. The thin film transistor TFT1 has a gate electrode thereof connected to the gate line GL-A, a drain electrode thereof connected to the drain line DL and a source electrode thereof connected to one pole of the capacitance CPR. On the other hand, the thin film transistor TFT2 has a gate electrode thereof connected to the source electrode (one pole of the capacitance CPR) of the thin film transistor TFT1, a drain electrode thereof connected to the current supply line CSL and a source electrode thereof connected to the anode AD of the organic light emitting element OLED. A cathode CD of the organic light emitting element OLED constitutes the cathode film described in conjunction with the above-mentioned embodiments.

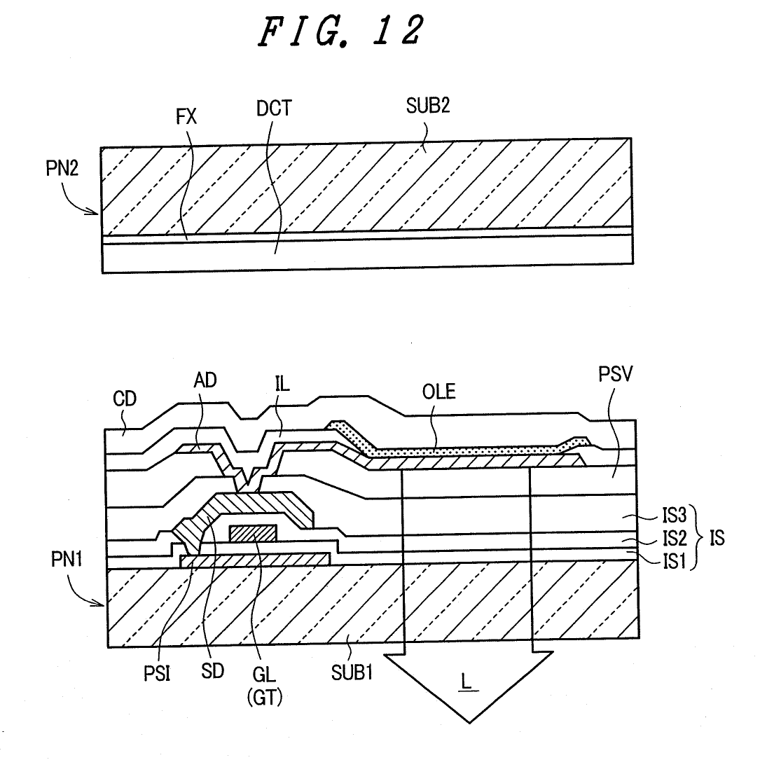

FIG. 12 is a cross-sectional view schematically showing an example of the layer structure in the vicinity of one pixel of the display device which uses an organic light emitting element to which the present invention is applied. On the main surface of the first substrate SUB1, there are thin film transistors, each of which is constituted of a poly-silicon semiconductor film PSI, a gate electrode GT (gate line GL), a source or a drain electrode SD (source electrode in the drawing). Reference symbol IS (IS1, IS2, IS3) indicates interlayer insulation layers and PSV indicates a passivation layer.

The thin film transistor shown in FIG. 12 corresponds to the thin film transistor TFT2 shown in FIG. 11. The anode AD which constitutes the organic light emitting element is connected to the source electrode SD, and the light emitting layer OLE is formed on the anode AD. Further, cathode film CD is formed on the light emitting layer OLE as an upper layer. On the other hand, on the inner surface of the second substrate SUB2, the moisture absorbent layer DCT is mounted using an adhesive agent FX for mainly preventing deterioration of the light emitting layer OLE caused by moisture. The present invention displays images with the pixels which are constituted in the above-mentioned manner.

As has been explained heretofore, according to the present invention, by providing the light shielding means close to the display area on which the pixel circuits that are to be blocked from the ultraviolet rays are formed and the drive circuit area where the drive circuits are formed, it is possible to cause the ultraviolet rays to be irradiated to only the seal material in the seal area, without using a special light shielding device in the manufacturing process; and, hence, it is possible to prevent the deterioration of characteristics of the organic light emitting layer and the semiconductor films which constitute the pixel circuits and the semiconductor films which constitute the drive circuits, whereby a display device of high quality can be obtained.

1. A display device comprising:
a first substrate having a display area in which a plurality of pixels are arranged in a matrix manner on a main surface of the first substrate and a first seal area formed at a periphery of the display area on the main surface of the first substrate, each of the plurality of pixels includes a light emitting element and a pixel circuit including an active element; and
a second substrate disposed to cover the main surface of the first substrate with a main surface of the second substrate, and having a second seal area at a part of the main surface of the second substrate opposite to the first seal area of the first substrate, the first substrate and the second substrate are stuck to each other by a seal material interposed between the first seal area and the second seal area; wherein the seal material is an ultraviolet ray curable material;
wherein at least one driving circuit which drives the plurality of pixels is arranged outside of the display area on the main surface of the first substrate;
wherein the second substrate has a recessed portion formed at a part of the main surface of the second substrate within the second seal area;
wherein a film coats one of the recessed portion of the second substrate and an outside of the second substrate so as to extend over an area which covers the display area and an area of the at least one driving circuit provided on the main surface of the first substrate;
wherein the film is one of a metal film and a resin film having carbon black or titanium black; and
wherein a moisture absorbent layer is arranged in the recessed portion of the second substrate so as to be adhered to one of the recessed portion and the film when the film coats the recessed portion.

2. A display device according to claim 1, wherein the film which extend over the area which covers the display area and the area of the at least one driving circuit provided on the main surface of the first substrate is the metal film which is coated on the recessed portion of the second substrate, and the moisture absorbent layer is adhered to the metal film coated on the recessed portion of the second substrate.

3. A display device according to claim 1, wherein the film which extends over the area which covers the display area and the area of the at least one driving circuit provided on the main surface of the first substrate is the metal film which is coated on the outside of the second substrate, and the moisture absorbent layer is adhered to the recessed portion of the second substrate.

4. A display device according to claim 1, wherein the film which extends over the area which covers the display area and the area of the at least one driving circuit provided on the main surface of the first substrate is the resin film having carbon black or titanium black which is coated on the outside of the second substrate, and the moisture absorbent layer is adhered to the recessed portion of the second substrate.

5. A display device according to claim 1, wherein the film which extends over the area which covers the display area and the area of the at least one driving circuit provided on the main surface of the substrate is a resin film having carbon black or titanium black which is coated on the recessed portion of the second substrate, and the moisture absorbent layer is adhered to the resin film which coats the recessed portion.

6. A display device according to claim 1, wherein the film enables shielding of the display area and the area of the at least one driving circuit provided on the main surface of the first substrate when the sealing material is cured by the ultraviolet ray.

7. A display device according to claim 1, wherein the film which coats the one of the recessed portion and outside of the second substrate enables maintenance of voltage/current characteristics of the display device so as to enable a display device of high quality at low cost.
